(19) United States
(12) Patent Application Publication
(10) Pub. No.: US 2019/0366682 A1
(43) Pub. Date: Dec. 5, 2019

(54) DEVICE SURFACE RENEWAL AND REWORK BY BUNDLED LAMINATE STRUCTURES

(71) Applicant: CORNING INCORPORATED, Corning, NY (US)

(72) Inventors: Dana Craig Bookbinder, Corning, NY (US); Jean-Marc Martin Gerard Jouanno, Thomery (FR); Govindarajan Natarajan, Poughkeepsie, NY (US); David Lee Weidman, Corning, NY (US); Nathaniel David Wetmore, Corning, NY (US)

(21) Appl. No.: 16/425,345

(22) Filed: May 29, 2019

Related U.S. Application Data
(60) Provisional application No. 62/678,594, filed on May 31, 2018.

(51) Int. Cl. B32B 7/06; B32B 7/12; B32B 17/00; H05K 5/00; H05K 5/03

(52) U.S. Cl. CPC B32B 7/06; B32B 7/12; B32B 17/00; H05K 5/0017; B32B 2307/412; B32B 2307/756; B32B 2307/584; B32B 2457/20; H05K 5/03

(57) ABSTRACT

A laminate structure is provided that allows the surface renewal and rework of a device by the selective removal of layers of the laminate. The selective removal may be achieved by heating or irradiating the laminate structure, such that an adhesive layer debonds and allows the removal of a damaged layer to provide a pristine surface.

### CROSS-REFERENCE TO RELATED APPLICATIONS

This application claims the benefit of priority under 35 U.S.C. § 119 of U.S. Provisional Application Ser. No. 62/678,594 filed on May 31, 2018, the content of which is relied upon and incorporated herein by reference in its entirety.

### BACKGROUND

### Field

The present specification generally relates to articles allowing selective renewal of surfaces. More specifically, the present specification is directed to laminate articles allowing selective surface renewal for various applications, such as use in electronic devices.

### Technical Background

The mobile nature of portable devices, such as smart phones, tablets, portable media players, personal computers, and cameras, makes these devices particularly vulnerable to accidental sharp impacts, such as dropping a portable device on hard surfaces. These devices typically incorporate cover glasses, which may become damaged upon impact with hard surfaces and may accumulate imperfections in normal use. In many of these devices, the cover glasses function as display covers, and may incorporate touch functionality, such that use of the devices is negatively impacted when the cover glasses are damaged. For example, imperfections in the cover glass may degrade the optical performance of the cover glass, which negatively impacts the performance of the device.

Additionally, the indentations produced by sharp contact with the cover glass may become failure sites in the glass surface from which cracks may develop and propagate. The fracture of the cover glass may render the device unsuitable for use.

Accordingly, a need exists for cover glass solutions that allow the renewal of the surface after accumulation of imperfections or fracture.

### SUMMARY

According to aspect (1), an article is provided. The article comprises: a first glass-based layer including a first surface and an opposing second surface; a first adhesive layer bonded to the second surface of the first glass-based layer; a second adhesive layer bonded to the first surface of the first glass-based layer; and a second glass-based layer including a first surface and an opposing second surface. The second surface of the second glass-based layer is bonded to the second adhesive layer. The first adhesive layer and the second adhesive layer have a peel strength of greater than or equal to 2 N/25 mm. The first adhesive layer is thermally debondable at a first temperature, and the second adhesive layer is thermally debondable at a second temperature. The first temperature is greater than the second temperature.

According to aspect (2), the article of aspect (1) is provided, further comprising a substrate, wherein the first adhesive layer is bonded to the substrate.

According to aspect (3), the article of aspect (1) or (2) is provided, wherein the first adhesive layer and the second adhesive layer have a peel strength of greater than or equal to 10 N/25 mm.

According to aspect (4), the article of any of aspects (1) to (3) is provided, wherein the first adhesive layer and the second adhesive layer have a peel strength of greater than or equal to 20 N/25 mm.

According to aspect (5), the article of any of aspects (1) to (4) is provided, wherein at least one of the first glass-based layer and the second glass based layer is ion exchanged.

According to aspect (6), the article of any of aspects (1) to (5) is provided, wherein at least one of the first glass-based layer and the second glass based layer comprises a glass ceramic.

According to aspect (7), the article of any of aspects (1) to (6) is provided, wherein at least one of the first adhesive layer and the second adhesive layer comprise an optically clear adhesive.

According to aspect (8), the article of any of aspects (1) to (7) is provided, wherein the first adhesive layer and the second adhesive layer have a light transmission greater than 85% in the visible spectrum.

According to aspect (9), the article of any of aspects (1) to (8) is provided, wherein the first adhesive layer and the second adhesive layer are transparent in the visible spectrum.

According to aspect (10), the article of any of aspects (1) to (9) is provided, wherein the first adhesive layer and the second adhesive layer are colorless.

According to aspect (11), the article of any of aspects (1) to (10) is provided, further comprising: a third glass-based layer including a first surface and an opposing second surface; and a third adhesive layer bonded to the second surface of the third glass-based layer and the first surface of the second glass-based layer. The third adhesive layer has a bond strength of greater than or equal to 2 N/25 mm. The third adhesive layer is thermally debondable at a third temperature, and the second temperature is greater than the third temperature.

According to aspect (12), a consumer electronic product is provided. The consumer electronic product comprises: a housing having a front surface, a back surface and side surfaces; electrical components provided at least partially within the housing, the electrical components including at least a controller, a memory, and a display, the display being provided at or adjacent to the front surface of the housing; and a cover substrate disposed over the display. At least one of a portion of the housing or a portion of the cover substrate comprises the article of any of aspects (1) to (11).

According to aspect (13), a headlight assembly is provided. The headlight assembly comprises the article of any of aspects (1) to (11).

According to aspect (14), an article is provided. The article comprises: a first glass-based layer including a first surface and an opposing second surface; a first adhesive layer bonded to the second surface of the first glass-based layer; a second adhesive layer bonded to the first surface of the first glass-based layer; and a second glass-based layer including a first surface and an opposing second surface, wherein the second surface of the second glass-based layer is bonded to the second adhesive layer. The first adhesive layer and the second adhesive layer have a peel strength of greater than or equal to 2 N/25 mm. The first adhesive layer is debondable when irradiated at a first wavelength, and the second adhesive layer is debondable when irradiated at a second wavelength. The first wavelength is different than the second wavelength.

According to aspect (15), the article of aspect (14) is provided, further comprising a substrate, wherein the first adhesive layer is bonded to the substrate.

According to aspect (16), the article of aspect (14) or (15) is provided, wherein the first adhesive layer and the second adhesive layer have a peel strength of greater than or equal to 10 N/25 mm.

According to aspect (17), the article of any of aspects (14) to (16) is provided, wherein the first adhesive layer and the second adhesive layer have a peel strength of greater than or equal to 20 N/25 mm.

According to aspect (18), the article of any of aspects (14) to (17) is provided, wherein at least one of the first glass-based layer and the second glass based layer is ion exchanged.

According to aspect (19), the article of any of aspects (14) to (18) is provided, wherein at least one of the first glass-based layer and the second glass based layer comprises a glass ceramic.

According to aspect (20), the article of any of aspects (14) to (19) is provided, wherein at least one of the first adhesive layer and the second adhesive layer comprise an optically clear adhesive.

According to aspect (21), the article of any of aspects (14) to (20) is provided, wherein the first adhesive layer and the second adhesive layer have a light transmission greater than 85% in the visible spectrum.

According to aspect (22), the article of any of aspects (14) to (21) is provided, wherein the first adhesive layer and the second adhesive layer are transparent in the visible spectrum.

According to aspect (23), the article of any of aspects (14) to (22) is provided, wherein the first adhesive layer and the second adhesive layer are colorless.

According to aspect (24), the article of any of aspects (14) to (23) is provided, wherein at least one of the first wavelength and the second wavelength are from 10 nm to 400 nm.

According to aspect (25), a consumer electronic product is provided. The consumer electronic device comprises: a housing having a front surface, a back surface and side surfaces; electrical components provided at least partially within the housing, the electrical components including at least a controller, a memory, and a display, the display being provided at or adjacent to the front surface of the housing; and a cover substrate disposed over the display. At least one of a portion of the housing or a portion of the cover substrate comprises the article of any of aspects (14) to (24).

According to aspect (26), a headlight assembly is provided. The headlight assembly comprises the article of any of aspects (14) to (24).

According to aspect (27), a method is provided. The method comprises: debonding a second glass-based layer from a laminated article, and removing the second glass-based layer from the laminated article. The laminated article comprises: a first glass-based layer including a first surface and an opposing second surface; a first adhesive layer bonded to the second surface of the first glass-based layer; a second adhesive layer bonded to the first surface of the first glass-based layer; and the second glass-based layer including a first surface and an opposing second surface. The second surface of the second glass-based layer is bonded to the second adhesive layer. The first adhesive layer and the second adhesive layer have a peel strength of greater than or equal to 2 N/25 mm. The debonding comprises at least one of heating the laminated article and irradiating the laminated article to remove the second adhesive layer, and the debonding does not reduce the peel strength of the first adhesive layer.

According to aspect (28), the method of aspect (27) is provided, wherein the debonding comprises heating the laminated article.

According to aspect (29), the method of aspect (27) is provided, wherein the debonding comprises irradiating the laminated article.

According to aspect (30), the method of aspect (27) is provided, wherein the debonding comprises irradiating the laminated article with light having a wavelength in the range of 10 nm to 400 nm.

According to aspect (31), the method of any of aspects (27) to (30) is provided, further comprising removing a residue from the first surface of the first glass-based layer after removing the second glass-based layer.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a cross section of an article according to embodiments disclosed and described herein;

FIG. 2 schematically depicts a cross section of an article according to embodiments disclosed and described herein;

FIG. 3A is a plan view of an exemplary electronic device incorporating any of the glass articles disclosed herein; and

FIG. 3B is a perspective view of the exemplary electronic device of FIG. 3A.

### DETAILED DESCRIPTION

Reference will now be made in detail to laminate structures and methods of renewing a surface thereof according to various embodiments.

Protection and renewal of device surfaces that experience degradation and damage during normal use extends the useful lifetime of the device. For example, the cover glass protecting a display of an electronic device may be scratched or pitted through the course of normal use, degrading the optical performance of the display and negatively impacting the user experience. Similarly, automobile headlight lenses acquire pitting and scratches during use when striking debris at speed. This damage may produce an undesirably hazy appearance and reduced effectiveness.

In an effort to address this type of damage that occurs through normal use, a variety of after-market and user applied protective solutions have been developed. For example, glass or plastic screen protectors are commonly applied to electronic devices, and protective films have been applied to headlight lenses. Such user applied solutions are susceptible to user error in application that may result in bubbles or misalignment that degrade the optical performance of the device. Additionally, any damage that is present on the surfaces to which these protective elements are applied is still present after application, such that these user applied solutions are not capable of restoring a used device to like-new condition. These user applied solutions generally employ temporary adhesives with a low peel strength, which may result in unintended debonding during the course of normal use which limits the effectiveness of these solutions.

The laminate structures described herein utilize adhesives to bond a plurality of glass-based layers, where the adhesives are selected to have a suitable peel strength to avoid unintentional debonding. The adhesives are selected to be debondable when exposed to a desired temperature or irradiated. The debonding conditions for the adhesives are selected to be different such that the glass-based layers may be selectively debonded and removed to expose a pristine surface. The adhesives may have optical properties that match those of the glass-based layers, such that the laminate structures have similar or equivalent optical performance to a single glass-based layer.

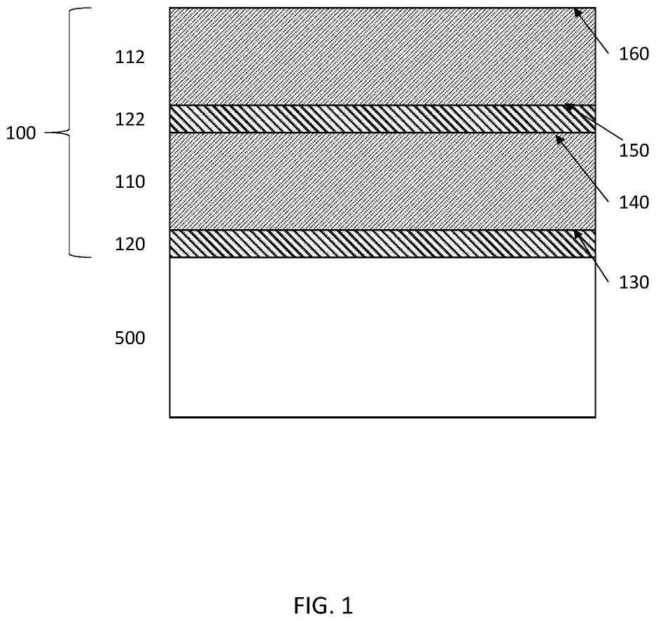

The laminate structures include at least two glass-based layers and at least two adhesive layers. FIG. 1 depicts a cross-section of a laminate structure 100 including a first glass-based layer 110 having a first surface 140 and a second surface 130 and second glass-based layer 112 having a first surface 160 and a second surface 150. In FIG. 1 the first surfaces 140/160 correspond to the top surface and the second surfaces 130/150 correspond to the bottom surfaces, but this is merely exemplary. A first adhesive layer 120 is bonded to the second surface 130 of the first glass-based layer 110. A second adhesive layer 122 is bonded to the first surface 140 of the first glass-based layer 110 and the second surface 150 of the second glass-based layer 112. The first adhesive layer 120 may also optionally be bonded to a substrate 500. The first adhesive layer 120 and the second adhesive layer 122 are debondable under different conditions, such as different temperatures or wavelengths. In the event that the first and second adhesive layers are debondable at different temperatures, the first adhesive layer is debondable at a higher temperature than the second adhesive layer.

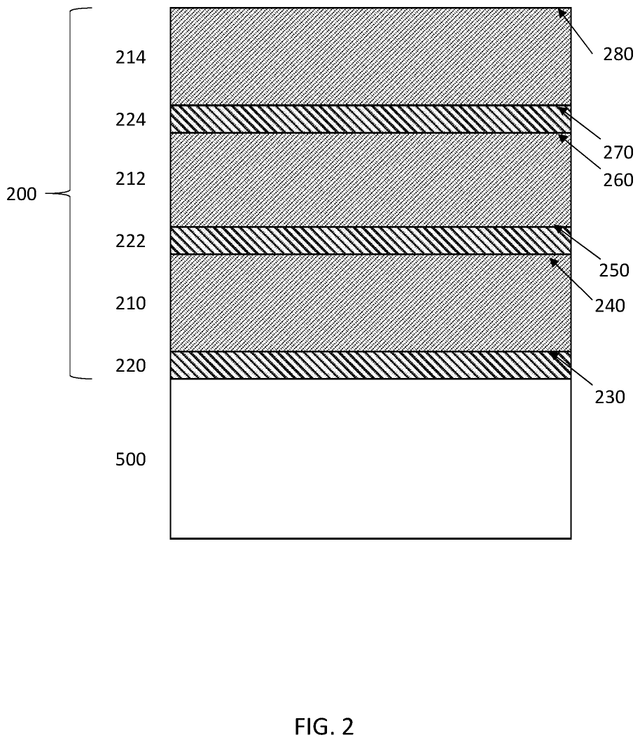

A laminate structure 200 including three glass-based layers and three adhesive layers is depicted in FIG. 2. The laminate structure 200 includes a first glass-based layer 210 having a first surface 240 and a second surface 230, a second glass-based layer 212 having a first surface 260 and a second surface 250, and a third glass-based layer 214 having a first surface 280 and a second surface 270. In FIG. 2 the first surfaces 240/260/280 correspond to the top surface and the second surfaces 230/250/270 correspond to the bottom surfaces, but this is merely exemplary. A first adhesive layer 220 is bonded to the second surface 230 of the first glass-based layer 210. A second adhesive layer 222 is bonded to the first 240 surface of the first glass-based layer 210 and the second surface 250 of the second glass-based layer 212. A third adhesive layer 224 is bonded to the first surface 260 of the second glass-based layer 212 and the second surface 270 of the third glass-based layer 214. The first adhesive layer 220 may also optionally be bonded to a substrate 500. The first adhesive layer 220, the second adhesive layer 222, and the third adhesive layer 224 are debondable under different conditions, such as different temperatures or wavelengths. In the event that the first, second, and third adhesive layers are debondable at different temperatures, the first adhesive layer is debondable at a higher temperature than the second adhesive layer and the third adhesive layer is debondable at a lower temperature than the second adhesive layer. The laminate structures described herein may include any appropriate number of glass-based layers and adhesive layers, continuing the layout shown in FIGS. 1 and 2.

With reference to FIG. 1 and FIG. 2, the first surface 160 of the second glass-based layer 112 and the first surface 280 of the third glass-based layer 214, respectively, is exposed when the laminate structure is incorporated into articles and subjected to normal use. In such cases, the substrate 500 may be a display or headlight lens, among other components. When the exposed surface 160/280 of the glass-based layer 112/214 is damaged, the adhesive layer 122/224 may be debonded by heating or irradiating the laminate structure. The debonding releases the glass-based layer 112/214 from the laminate structure 100/200, allowing the removal of the glass-based layer to expose the first surface 140/260 of the glass-based layer 110/212. The first surface 140/260 of the glass-based layer 110/212 is pristine and free of defects, effectively renewing the surface of the laminate structure. In embodiments, residue from the debonded adhesive layer may be removed from the first surface 140/260 of the glass-based layer 110/212, such as by rinsing, wiping, or washing. The same technique may be employed to remove additional glass-based layers from the laminate structure.

The adhesive layers may be any appropriate adhesive. In embodiments, the adhesive produces a strong bond, such as a bond with a peel strength of greater than or equal to 2 N/25 mm. Adhesives with peel strengths of greater than or equal to 2 N/25 mm may be sufficient to avoid unintentional debonding. In embodiments, the adhesive layers may have a peel strength greater than or equal to 10 N/25 mm, such as greater than or equal to 20 N/25 mm. The adhesive layers in the laminate structure may have the same or different peel strengths.

The peel strength values recited herein are measured and reported according to ASTM D3330 and JIS-Z-0237 using a commercially available peel strength tester.

The adhesive layers may be formed from any appropriate material. In embodiments, the adhesive layers may be a resin or epoxy. In some embodiments, the adhesive layers are formed from optically clear adhesives. In embodiments, the adhesive layers may be acrylates or silicones. Non-limiting examples of adhesives that may be utilized to form the adhesive layers include: PS-213VTE#50, PS-2115TE, PS-2021TE, PS-213VTE#100, and PS-2011TE produced by SOMAR Corporation; Intelimer 6914T14 and 6914T13 produced by NITTA Corporation; Revalpha produced by Nitta Denko; NE-GE60UV120, NE-GE80UV120, MHM-GA25, MHM-GA50 produced by Nichie Kakoh; and Valtron Epoxy AD4010-A and AD4015-B produced by Valtech. In embodiments, the adhesive layers include dry-type adhesives, such as dry film adhesives. In embodiments, the adhesive layers include flowable adhesives or semi-flowable adhesives.

The adhesive layers may be selectively debondable when heated or irradiated. Without wishing to be bound by any particular theory, the adhesive layers may expand when debonded such that adhesion between the adhesive layer and the adjacent glass-based layers is reduced or eliminated, allowing the removal of the external glass-based layer. The adhesive layers in the laminate structure are selected to have different debonding conditions. In this manner, a single adhesive layer may be selectively debonded while the remaining adhesive layers remain bonded, allowing removal of only the desired glass-based layer. In some embodiments, all of the adhesive layers are selected to be debondable by heating or all of the adhesive layers are selected to be debondable by irradiation. In other embodiments, the adhesive layers are selected to have a mixture of adhesive layers debondable by heating (i.e., thermally debondable) and adhesive layers debondable by irradiation.

The thermally debondable adhesive layers may be debondable by heating to any appropriate temperature. In embodiments, the adhesive layers may be debondable at a temperature in the range from greater than or equal to 60° C. to less than or equal to 200° C., such as from greater than or equal to 70° C. to less than or equal to 190° C., from greater than or equal to 80° C. to less than or equal to 180° C., from greater than or equal to 90° C. to less than or equal to 170° C., from greater than or equal to 100° C. to less than or equal to 160° C., from greater than or equal to 110° C. to less than or equal to 150° C., from greater than or equal to 120° C. to less than or equal to 140° C., or equal to 130° C., and any and all sub-ranges and ranges between any of the foregoing endpoints. Where more than one adhesive layer is thermally debondable, the adhesive layer closest to the exposed surface of the laminate structure has a debonding temperature that is lower than the debonding temperature of any adhesive layer that is located further from the exposed surface of the laminate structure. This allows the outermost thermally debondable adhesive layer to be heated to its debonding temperature without debonding or reducing the peel strength of the thermally debondable adhesive layers that are located further from the exposed surface of the laminate structure.

The adhesive layers debondable by irradiation may be debondable in response to irradiation at any appropriate wavelength and intensity. In embodiments, the adhesive layers may be debondable by irradiation with ultraviolet (UV) light, such as irradiation with light at a wavelength from greater than or equal to 10 nm to less than or equal to 400 nm. In embodiments, the adhesive layers may be debondable by irradiation at a given intensity. When more than one adhesive layer in the laminate structure is debondable by irradiation, the adhesive layers debondable by irradiation each are debondable at different wavelengths and/or intensities. This allows a single adhesive layer to be debonded by selecting the corresponding irradiation wavelength and intensity, and accordingly the removal of only the desired glass-based layer without reducing the peel strength of the other adhesive layers.

The adhesive layers may have any appropriate optical properties. In embodiments, the adhesive layers may be transparent in the visible spectrum. As utilized herein, the “visible spectrum” includes the wavelengths from 390 nm to 700 nm. In embodiments, the adhesive layers may have a light transmission of greater than or equal to 85% in the visible spectrum, or more. The adhesive layers may be colorless. In embodiments the adhesive layers may be optically clear. In embodiments, the adhesive layers may be selected to match the optical properties of the glass-based layers, such that the optical performance of the laminate structure is substantially equivalent to the optical performance of a single glass-based layer. In embodiments, non-optically clear adhesives may be utilized.

The adhesive layers may have any appropriate thickness. In embodiments, the adhesive layers may have a thickness that is less than or equal to the thickness of the glass-based layers. In other embodiments, the adhesive layers may have a thickness that is greater than the thickness of the glass-based layers.

The adhesive layers thermally debondable by heating may be heated and debonded by any appropriate process. In embodiments, the heating may be carried out with an oven, a heat gun, a heated water jacket or bottle, or heating pad. The heating method is controllable to a temperature sufficiently precise to avoid heating non-target adhesive layers to the associated debonding temperature.

The adhesive layers debondable by irradiation may be irradiated by any appropriate light source. In embodiments, the light source may be a mercury lamp, a laser, light emitting diode, or other appropriate ultraviolet light source. The irradiation method is controllable to a wavelength sufficiently precise to avoid irradiating non-target adhesive layers at the associated debonding wavelength and intensity.

As utilized herein, the term “glass-based” indicates an article that includes a glass, such as glass or glass-ceramic compositions. The glass-based layers included in the laminate structure may include glass and/or glass-ceramic compositions. The glass-based layers may be strengthened and include a compressive stress layer extending from a surface of the glass-based layer to a depth of compression.

The glass-based layers may have any appropriate composition. In some embodiments, the glass-based layers may include aluminosilicates. For example, when the glass-based layer is subjected to ion exchange strengthening processes, the glass-based layer may include an alkali aluminosilicate, where the alkali component facilitates the ion exchange process. The glass-based layers may include other compositional components where the effect of those components is desired.

The glass-based layers may have any suitable thickness. In embodiments, the glass-based layers may have a thickness from greater than or equal to 0.1 mm to less than or equal to 2.0 mm, such as from greater than or equal to 0.2 mm to less than or equal to 1.0 mm, from greater than or equal to 0.3 mm to less than or equal to 0.9 mm, from greater than or equal to 0.4 mm to less than or equal to 0.8 mm, from greater than or equal to 0.5 mm to less than or equal to 0.7 mm, or equal to 0.5 mm, and all ranges and sub-ranges between the foregoing values.

In embodiments, the glass-based layers may be transparent in the visible spectrum. Similarly, in embodiments the glass-based layers may be colorless.

The glass-based layers according to embodiments may be formed by any suitable method, such as slot forming, float forming, rolling processes, fusion forming processes, etc. The glass-based layers may be characterized by the manner in which it may be formed. For instance, the glass-based layer may be characterized as float-formable (i.e., formed by a float process), down-drawable and, in particular, fusion-formable or slot-drawable (i.e., formed by a down draw process such as a fusion draw process or a slot draw process).

Some embodiments of the glass-based layers described herein may be formed by a down-draw process. Down-draw processes produce glass articles having a uniform thickness that possess relatively pristine surfaces. Because the average flexural strength of the glass article is controlled by the amount and size of surface flaws, a pristine surface that has had minimal contact has a higher initial strength. In addition, down drawn glass articles have a very flat, smooth surface that can be used in its final application without costly grinding and polishing.

Some embodiments of the glass-based layers may be described as fusion-formable (i.e., formable using a fusion draw process). The fusion process uses a drawing tank that has a channel for accepting molten glass raw material. The channel has weirs that are open at the top along the length of the channel on both sides of the channel. When the channel fills with molten material, the molten glass overflows the weirs. Due to gravity, the molten glass flows down the outside surfaces of the drawing tank as two flowing glass films. These outside surfaces of the drawing tank extend down and inwardly so that they join at an edge below the drawing tank. The two flowing glass films join at this edge to fuse and form a single flowing glass article. The fusion draw method offers the advantage that, because the two glass films flowing over the channel fuse together, neither of the outside surfaces of the resulting glass article comes in contact with any part of the apparatus. Thus, the surface properties of the fusion drawn glass article are not affected by such contact.

Some embodiments of the glass-based layers described herein may be formed by a slot draw process. The slot draw process is distinct from the fusion draw method. In slot draw processes, the molten raw material glass is provided to a drawing tank. The bottom of the drawing tank has an open slot with a nozzle that extends the length of the slot. The molten glass flows through the slot/nozzle and is drawn downward as a continuous glass article and into an annealing region.

In one or more embodiments, the glass-based layers described herein may exhibit an amorphous microstructure and may be substantially free of crystals or crystallites. In other words, the glass-based layers exclude glass-ceramic materials in some embodiments.

In one or more embodiments, the glass-based layers include glass-ceramic materials having an amorphous phase and one or more crystalline phases. The glass-ceramic materials may have any appropriate crystal structure. In some embodiments, the glass-ceramic materials may include a crystal structure selected from lithium silicate, petalite, beta-spodumene, spinel, and others commonly employed in the art.

The glass-based layers may include additional coatings to provide desired effects. In embodiments, one or more of the glass-based layers may include one or more of an anti-glare coating, an anti-reflective coating, an oleophobic coating, and a hydrophobic coating. In embodiments, the glass-based layers may include an antimicrobial coating or layer. In some embodiments, the glass-based layers may additionally include decorative coatings, such as those formed by ink, decals, or engraving.

The strengthened glass-based layers may include a first region under compressive stress extending from the surface to a depth of compression (DOC) of the glass and a second region under a tensile stress or central tension (CT) extending from the DOC into the central or interior region of the glass. As used herein, DOC refers to the depth at which the stress within the glass article changes from compressive to tensile. At the DOC, the stress crosses from a positive (compressive) stress to a negative (tensile) stress and thus exhibits a stress value of zero.

According to the convention normally used in the art, compression or compressive stress is expressed as a negative (<0) stress and tension or tensile stress is expressed as a positive (>0) stress. Throughout this description, however, CS is expressed as a positive or absolute value—i.e., as recited herein, CS=|CS|. The compressive stress (CS) has a maximum at or near the surface of the glass, and the CS varies with distance d from the surface according to a function. Compressive stress (including surface CS) is measured by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety.

In some embodiments, the CS of the glass-based layer is from greater than or equal to 100 MPa to less than or equal to 1300 MPa, such as from greater than or equal to 150 MPa to less than or equal to 1200 MPa, from greater than or equal to 200 MPa to less than or equal to 1100 MPa, from greater than or equal to 250 MPa to less than or equal to 1000 MPa, from greater than or equal to 250 MPa to less than or equal to 950 MPa, from greater than or equal to 300 MPa to less than or equal to 900 MPa, from greater than or equal to 350 MPa to less than or equal to 850 MPa, from greater than or equal to 400 MPa to less than or equal to 800 MPa, from greater than or equal to 450 MPa to less than or equal to 750 MPa, from greater than or equal to 500 MPa to less than or equal to 700 MPa, from greater than or equal to 550 MPa to less than or equal to 650 MPa, or equal to 600 MPa, and all ranges and sub-ranges between the foregoing values.

The compressive stress of the glass-based layer is balanced by stored tension in the central region of the glass. The maximum central tension (CT) and DOC values are measured using a scattered light polariscope (SCALP) technique known in the art. The Refracted near-field (RNF) method or SCALP may be used to measure the stress profile. When the RNF method is utilized to measure the stress profile, the maximum CT value provided by SCALP is utilized in the RNF method. In particular, the stress profile measured by RNF is force balanced and calibrated to the maximum CT value provided by a SCALP measurement. The RNF method is described in U.S. Pat. No. 8,854,623, entitled “Systems and methods for measuring a profile characteristic of a glass sample”, which is incorporated herein by reference in its entirety. In particular, the RNF method includes placing the glass article adjacent to a reference block, generating a polarization-switched light beam that is switched between orthogonal polarizations at a rate of between 1 Hz and 50 Hz, measuring an amount of power in the polarization-switched light beam and generating a polarization-switched reference signal, wherein the measured amounts of power in each of the orthogonal polarizations are within 50% of each other. The method further includes transmitting the polarization-switched light beam through the glass sample and reference block for different depths into the glass sample, then relaying the transmitted polarization-switched light beam to a signal photodetector using a relay optical system, with the signal photodetector generating a polarization-switched detector signal. The method also includes dividing the detector signal by the reference signal to form a normalized detector signal and determining the profile characteristic of the glass sample from the normalized detector signal.

In embodiments, the glass-based layers may have a maximum CT from greater than or equal to 60 MPa to less than or equal to 200 MPa, such as from greater than or equal to 70 MPa to less than or equal to 190 MPa, from greater than or equal to 80 MPa to less than or equal to 180 MPa, from greater than or equal to 90 MPa to less than or equal to 170 MPa, from greater than or equal to 100 MPa to less than or equal to 160 MPa, from greater than or equal to 110 MPa to less than or equal to 150 MPa, from greater than or equal to 120 MPa to less than or equal to 140 MPa, or equal to 130 MPa, and all ranges and sub-ranges between the foregoing values.

As noted above, DOC is measured using a scattered light polariscope (SCALP) technique known in the art. The DOC is provided in some embodiments herein as a portion of the thickness (t) of the glass-based layer. In embodiments, the glass-based layer may have a depth of compression (DOC) from greater than or equal to 0.10 t to less than or equal to 0.30 t, such as from greater than or equal to 0.11 t to less than or equal to 0.29 t, from greater than or equal to 0.12 t to less than or equal to 0.28 t, from greater than or equal to 0.13 to less than or equal to 0.27 t, from greater than or equal to 0.14 t to less than or equal to 0.26 t, from greater than or equal to 0.15 t to less than or equal to 0.25 t, from greater than or equal to 0.16 t to less than or equal to 0.24 t, from greater than or equal to 0.17 t to less than or equal to 0.23 t, from greater than or equal to 0.18 t to less than or equal to 0.22 t, from greater than or equal to 0.19 t to less than or equal to 0.21 t, or equal to 0.20 t, and all ranges and sub-ranges between the foregoing values.

Compressive stress layers may be formed in the glass-based layers by exposing the glass-based layer to an ion exchange solution. In embodiments, the ion exchange solution may be one or more molten nitrate salts. In some embodiments, the ion exchange solution may be molten KNO₃, molten NaNO₃, or combinations thereof. In some embodiments, the ion exchange solution may additionally include lithium salts, such as LiNO₃.

The glass-based layer may be exposed to the ion exchange solution by dipping a glass-based substrate into a bath of the ion exchange solution, spraying the ion exchange solution onto a glass article made from the glass composition, or otherwise physically applying the ion exchange solution to a glass article made from the glass composition. Upon exposure to the glass-based substrate, the ion exchange solution may, according to embodiments, be at a temperature from greater than or equal to 340° C. to less than or equal to 500° C. In embodiments, the glass-based substrate may be exposed to the ion exchange solution for a duration from greater than or equal to 2 hours to less than or equal to 48 hours.

The ion exchange process may be performed in an ion exchange solution under processing conditions that provide an improved compressive stress profile as disclosed, for example, in U.S. Patent Application Publication No. 2016/0102011, which is incorporated herein by reference in its entirety. In some embodiments, the ion exchange process may be selected to form a parabolic stress profile in the glass-based layers, such as those stress profiles described in U.S. Patent Application Publication No. 2016/0102014, which is incorporated herein by reference in its entirety.

In embodiments, the glass-based layers may have any appropriate geometry. For example, the glass-based layers may be flat, or be formed into a non-planar shape. In embodiments, the glass-based layers may be subjected to cold forming or hot forming process to achieve the desired final shape. The shaping of the glass-based layers may occur before and/or after the assembly of the laminate structure.

The laminate structures described herein may be formed by any appropriate process. In embodiments, the laminate structures may be produced by disposing an adhesive layer over the surface of a glass-based layer, and then assembling the glass-based layers into a laminate structure. The adhesive layers may be disposed by any appropriate process, such as by a spray coating process, a roller process, or a doctor blade process. In embodiments, the laminate structure may be cut to the final size after the assembly of the glass-based layers and the adhesive layers, improving efficiency. Additionally, assembling the laminate structure reduces the incidence of bubbles and bonding failure, especially when compared to user applied protective materials. The assembly of the laminate structure in a controlled environment also ensures that the surfaces of the glass-based layers are pristine at the time of assembly, such that upon debonding a new pristine surface is exposed. In some embodiments a protective film may be applied to an exposed adhesive layer to protect the adhesive layer until later assembly with a substrate upon incorporation into a larger article. Insome embodiments, the laminate structure may be bonded to the substrate by an adhesive layer that is not thermally or UV debondable. In embodiments, the substrate may be an electronic display, consumer electronic housing, automobile headlight assembly, or dry erase marker board.

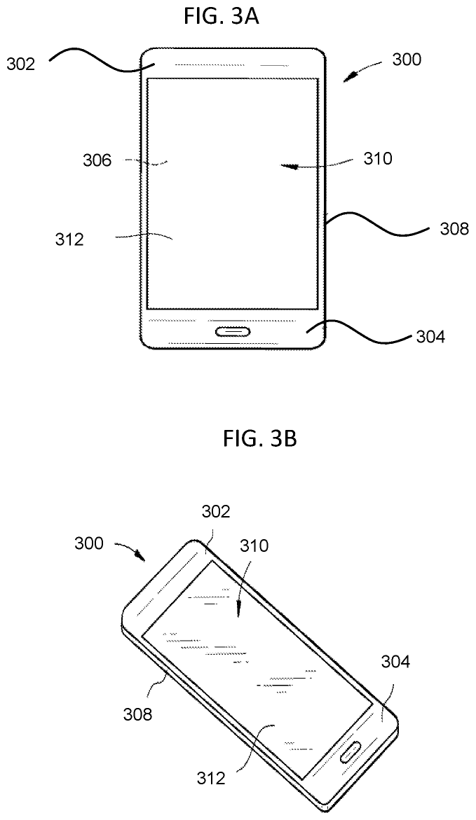

The laminated structures disclosed herein may be incorporated into another article such as an article with a display (or display articles) (e.g., consumer electronics, including mobile phones, tablets, computers, navigation systems, and the like), architectural articles, transportation articles (e.g., automobiles, trains, aircraft, sea craft, etc.), appliance articles, or any article that requires some transparency, scratch-resistance, abrasion resistance or a combination thereof. An exemplary article incorporating any of the laminated structures disclosed herein is shown in FIGS. 3A and 3B. Specifically, FIGS. 3A and 3B show a consumer electronic device 300 including a housing 302 having front 304, back 306, and side surfaces 308; electrical components (not shown) that are at least partially inside or entirely within the housing and including at least a controller, a memory, and a display 310 at or adjacent to the front surface of the housing; and a cover substrate 312 at or over the front surface of the housing such that it is over the display. In some embodiments, the cover substrate 312 and/or the housing may include any of the laminate structures disclosed herein. In embodiments, the laminate structures may be incorporated into an automobile headlight assembly.

### Examples

Embodiments will be further clarified by the following examples. It should be understood that these examples are not limiting to the embodiments described above.

A laminate structure was produced with two adhesive layers and two glass layers. The first adhesive layer was PS-213VTE#50 produced by SOMAR, and the second adhesive layer was Intellimer 6914T14 produced by NITTA. The first adhesive layer was bonded to the first surface of a substrate and the second surface of the first glass layer. The second adhesive layer was bonded to the first surface of the first glass layer and the second surface of the second glass layer. The adhesive layers had a peel strength above 10 N/25 mm.

The laminate structure was heated to a temperature of approximately 85° C., resulting in the debonding of the second adhesive layer and the removal of the second glass layer. The first adhesive layer remained bonded to the substrate and the first adhesive layer.

The laminate structure was then heated to a temperature of approximately 155° C., resulting in the debonding of the first adhesive layer and the removal of the first glass layer from the substrate.

This exemplary laminate structure demonstrated that it is possible to selectively debond adhesive layers to remove exposed glass layers from the structure, without debonding other adhesive layers within the laminate structure. This allows the effective renewal of the exposed surface of the laminate structure.

It will be apparent to those skilled in the art that various modifications and variations can be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. An article, comprising:
a first glass-based layer including a first surface and an opposing second surface;
a first adhesive layer bonded to the second surface of the first glass-based layer;
a second adhesive layer bonded to the first surface of the first glass-based layer; and
a second glass-based layer including a first surface and an opposing second surface, wherein the second surface of the second glass-based layer is bonded to the second adhesive layer,
wherein the first adhesive layer and the second adhesive layer have a peel strength of greater than or equal to 2 N/25 mm, the first adhesive layer is thermally debondable at a first temperature, the second adhesive layer is thermally debondable at a second temperature, and the first temperature is greater than the second temperature.

2. The article of claim 1, further comprising a substrate, wherein the first adhesive layer is bonded to the substrate.

3. The article of claim 1, wherein the first adhesive layer and the second adhesive layer have a peel strength of greater than or equal to 10 N/25 mm.

4. The article of claim 1, wherein at least one of the first glass-based layer and the second glass based layer is ion exchanged.

5. The article of claim 1, wherein at least one of the first glass-based layer and the second glass based layer comprises a glass ceramic.

6. The article of claim 1, wherein the first adhesive layer and the second adhesive layer have a light transmission greater than 85% in the visible spectrum.

7. The article of claim 1, further comprising:
a third glass-based layer including a first surface and an opposing second surface; and
a third adhesive layer bonded to the second surface of the third glass-based layer and the first surface of the second glass-based layer,
wherein the third adhesive layer has a bond strength of greater than or equal to 2 N/25 mm, the third adhesive layer is thermally debondable at a third temperature, and the second temperature is greater than the third temperature.

8. A consumer electronic product, comprising:
a housing having a front surface, a back surface and side surfaces;
electrical components provided at least partially within the housing, the electrical components including at least a controller, a memory, and a display, the display being provided at or adjacent to the front surface of the housing; and
a cover substrate disposed over the display,
wherein at least one of a portion of the housing or a portion of the cover substrate comprises the article of claim 1.

9. A headlight assembly, comprising the article of claim 1.

10. An article, comprising:
a first glass-based layer including a first surface and an opposing second surface;
a first adhesive layer bonded to the second surface of the first glass-based layer;
a second adhesive layer bonded to the first surface of the first glass-based layer; and
a second glass-based layer including a first surface and an opposing second surface, wherein the second surface of the second glass-based layer is bonded to the second adhesive layer,
wherein the first adhesive layer and the second adhesive layer have a peel strength of greater than or equal to 2 N/25 mm, the first adhesive layer is debondable when irradiated at a first wavelength, the second adhesive layer is debondable when irradiated at a second wavelength, and the first wavelength is different than the second wavelength.

11. The article of claim 10, further comprising a substrate, wherein the first adhesive layer is bonded to the substrate.

12. The article of claim 10, wherein the first adhesive layer and the second adhesive layer have a peel strength of greater than or equal to 10 N/25 mm.

13. The article of claim 10, wherein at least one of the first glass-based layer and the second glass based layer is ion exchanged.

14. The article of claim 10, wherein at least one of the first glass-based layer and the second glass based layer comprises a glass ceramic.

15. The article of claim 10, wherein the first adhesive layer and the second adhesive layer have a light transmission greater than 85% in the visible spectrum.

16. The article of claim 10, wherein the first adhesive layer and the second adhesive layer are colorless.

17. The article of claim 10, wherein at least one of the first wavelength and the second wavelength are from 10 nm to 400 nm.

18. A consumer electronic product, comprising:
a housing having a front surface, a back surface and side surfaces;
electrical components provided at least partially within the housing, the electrical components including at least a controller, a memory, and a display, the display being provided at or adjacent to the front surface of the housing; and
a cover substrate disposed over the display,
wherein at least one of a portion of the housing or a portion of the cover substrate comprises the article of claim 10.

19. A headlight assembly, comprising the article of claim 10.

20. A method, comprising:
debonding a second glass-based layer from a laminated article, wherein the laminated article comprises:
a first glass-based layer including a first surface and an opposing second surface;
a first adhesive layer bonded to the second surface of the first glass-based layer;
a second adhesive layer bonded to the first surface of the first glass-based layer; and
the second glass-based layer including a first surface and an opposing second surface, wherein the second surface of the second glass-based layer is bonded to the second adhesive layer,
wherein the first adhesive layer and the second adhesive layer have a peel strength of greater than or equal to 2 N/25 mm; and
removing the second glass-based layer from the laminated article,
wherein the debonding comprises at least one of heating the laminated article and irradiating the laminated article to remove the second adhesive layer, and the debonding does not reduce the peel strength of the first adhesive layer.
